(19) United States
(12) Patent Application Publication
(10) Pub. No.: US 2004/0179569 A1
(43) Pub. Date: Sep. 16, 2004

(54) Wavelength tunable DBR laser diode

(75) Inventors: Hiroshi Sato, Kokubunji (JP); Masahiro Aoki, Kokubunji (JP)

Correspondence Address: Stanley P. Fisher, Reed Smith LLP, Suite 1400, 3110 Fairview Park Drive, Falls Church, VA, 22042-4503, US

(73) Assignee: Hitachi., Ltd.

(21) Appl. No.: 10/756,402

(22) Filed: Jan. 14, 2004

(30) Foreign Application Priority Data
Mar. 12, 2003 (JP) 2003-066436

(51) Int. Cl. H01S 3/10; H01S 5/00; H01S 3/08

(52) U.S. Cl. 372/50; 372/20; 372/96

(57) ABSTRACT

The present invention concerns an optical transmission apparatus and provides a wavelength tunable DBR laser diode capable of minimizing change in optical power upon wavelength tuning and having a broad wavelength tunable range. The present invention provides a wavelength tuning DBR laser diode of a waveguide type optical device in which an active waveguide and a distributed Bragg reflector are optically combined in a predetermined section on a semiconductor substrate wherein at least one quantum well layer independent of the active waveguide is formed at a portion or the entire portion of the distributed Bragg reflector.

### BACKGROUND OF THE INVENTION

1. Field of the Invention

The present invention relates to a wavelength tunable DBR laser diode.

2. Related Art

Along with increase in the utilization of information communication services, operation speed and capacity of optical communication systems supporting them have been increased more and more. Among all, a WDM (Wavelength Domain Multiplexing) system is adapted to transmit optical signals at a plurality of wavelengths in a single optical fiber. Since the system can drastically improve the communication capacity without additionally providing optical fibers, the WDM system has already been progressed for commercial use.

The optical transmission device for WDM is provided with semiconductor lasers with wavelengths applicable to respective wavelength channels in most cases. However, in a case of providing independent semiconductor lasers for all of the channels, the size and cost of the apparatus are inevitably increased. Then, to realize a small sized and low cost WDB transmission apparatus, it has been demanded to develop a light source applicable to a plurality of wavelength channels by one device thereby decreasing the number of parts, the size and cost of the WDB transmission apparatus. Under such a background, a light source capable of optionally tuning the wavelength by a single device, that is, a wavelength tunable light source has been developed. Further, the wavelength tunable light source includes several types and an example of the development is described, for example, in Lecture No. C-4-3 in the 2001 Electronics Society Meeting of Electronic Information Communication Society or in the Electronics Engineering Articles of IEEE Journal of Lightwave Technology, vol. 17, No. 5 (1999), pp 918-923.

Among the wavelength tunable light sources developed so far, a promising light source capable of attaining wavelength switching at high speed includes a DBR (Distributed Bragg Refractor) laser. In the DBR laser, an active section and a DBR section are integrated and a wavelength can be tuned by injecting electric current to the DBR section. Since the principle of the wavelength tuning in the DBR laser has been known, only the outline is to be described here.

An optical waveguide layer and a diffraction grating are formed in the DBR section and the wavelength λ_{DBR} of the DBR laser is determined by a product of the refractive index N_{DBR} and the diffraction period A. Current is injected to the DBR section so that electrons are accumulated in the optical waveguide layer, and consequently the refractive index N_{DBR} of the optical guide layer changes. Generally, this is referred to as a plasma effect. On the other hand, since the DBR period Λ does not change by the current injection, the wavelength λ_{DBR} can be controlled.

The concept of providing the DBR section with a light amplifying function is reported in the Electronic Engineering Article of IEEE Photonics Technology Letters, vol. 3 No. 10, pp 886 to 868. In this report, it was attempted to dispose an active layer comprised of bulk in the DBR section to provide the DBR section with an amplifying function.

As has been described above in a case of tuning the wavelength by the DBR laser, electrons are accumulated in the optical waveguide layer of the DBR section. As is well-known, electrons accumulated in the waveguide cause free electron absorption to absorb light (photon) propagating through the waveguide. As a result, the intensity of light propagating through the DBR section is attenuated and the device output is lowered. FIGS. 1 and 2 show an example of the experimental result. FIG. 1 is a cross-sectional structural view of a device used in the experiment, taken along a plane parallel with the optical axis of an optical resonator. FIG. 2 is an example of device characteristics thereof.

The device structure is the same as that of a usual DBR laser. That is, an active section and a DBR section are mounted on an n-InP substrate. An n-InGaAsP optical confinement layer 102, a multiple quantum well active layer 103 and a p-InGaAsP optical confinement layer 104 constitute an active section. On the other hand, a diffraction grating layer 115 is formed of an InGaAsP layer above an InGaAsP optical confinement layer 111 on the n-InP substrate. Then, a common p-InP clad layer is formed above the active section and the DBR section. A P-Inp clad layer 121 and a p-InGaAs contact layer 122, separated by a silicon oxide film, are formed at positions corresponding to the active section and the DBR section, respectively. Further, a p-electrode 132 and a p-electrode 133 are formed at positions corresponding to the active section and DBR section, respectively. An n-electrode 131 is formed on the rear face of the substrate. A high-reflective film 135 and an anti-reflective film 132 are formed at respective crystal facets each including an emission face.

FIGS. 2A and 2B show the device characteristics. FIG. 2A shows a Light Current characteristics along with injection of a wavelength tuning current and FIG. 2B shows an oscillation wavelength and optical power take out efficiency upon injection of a wavelength tuning current. As shown in FIG. 2A, Light Current characteristics change in accordance with injection of the wavelength tuning current. Then, a section incapable of obtaining optical power also is encountered. FIG. 2B shows that wavelength changes from about 1559 nm to about 1551 nm in a range of the wavelength tuning current of 0 to 30 mA. In this case, the optical power efficiency also indicated in FIG. 2B is lowered by about 2 dB.

The lowering of the optical output power in accordance with the wavelength tuning results in additional problems such as provision of a circuit for tuning device optical power and restriction on the wavelength tuning section in view of practical use of the DBR laser as a wavelength tunable light source.

### SUMMARY OF THE INVENTION

It is an object of the present invention to solve the foregoing problems and utilize wavelength tuning characteristics to the utmost extent while minimizing reduction in optical output power. For this purpose, the invention proposes a structure in which a quantum well layer is introduced in an optical waveguide structure of a DBR section. The invention is characterized in that the quantum well structure formed in the DBR section has the following characteristics. First, the quantum well layer formed in the DBR section amplifies light with an oscillation wavelength. Then, since the quantum well layer lies in the DBR section, the quantum well layer itself for DBR does not cause laser oscillation. According to the invention having the foregoing feature, reduction in optical power upon wavelength tuning can be minimized. Naturally, the oscillation wavelength is controlled as usual by injecting current to the DBR section. The invention is to be described below.

At first, the amplifying function of the quantum well layer formed in the DBR section can compensate the attenuation of light caused upon wavelength tuning. This can minimizes the reduction in optical power upon wavelength tuning. However, this requires such a design as increasing the oscillation threshold gain of the quantum well layer introduced in the DBR section and the DBR section does not cause laser oscillation as described above. In a case where laser oscillation occurs in the DBR section, the section is no more DBR section but forms a DFB (Distributed Feedback) laser. As a result, the wavelength can no more be tuned and the intended purpose of the DBR laser cannot be attained.

The amplifying function of light with an oscillation wavelength in the quantum well formed in the DBR section is generated when the band gap wavelength of the quantum well formed in the DBR section overlaps with the oscillation wavelength. Usually, the band gap wavelength of the quantum well has a limited range with the peak wavelength at the top. Accordingly, it is preferred to set the peak (gain peak) of the band gap of the quantum well layer to a range of about from ±20 nm to ±30 nm.

Specifically, one of methods of not causing laser oscillation in the quantum well for DBR itself is a simple, effective method of decreasing the number of quantum wells in the DBR section. That is, it is necessary to adopt a structure in which the oscillation threshold gain of the quantum well in the DBR section is large. Since the threshold gain is high, even if gain occurs in the DBR section, the threshold value for the laser oscillation is not reached.

In the invention, the quantum well in the DBR section is made as a quantum well independent of the quantum well in the active section, so that the threshold gain is different between the active section (emission section) and the DBR section. The structure of the quantum well is designed to decrease the threshold gain such that oscillation is caused easily in the active section, whereas the structure of the quantum well is designed to increase the threshold gain in the DBR section.

### BRIEF DESCRIPTION OF THE DRAWINGS

FIG. 1 is a cross-sectional structural view of an existent device, taken along a plane parallel with the optical axis of an optical resonator;

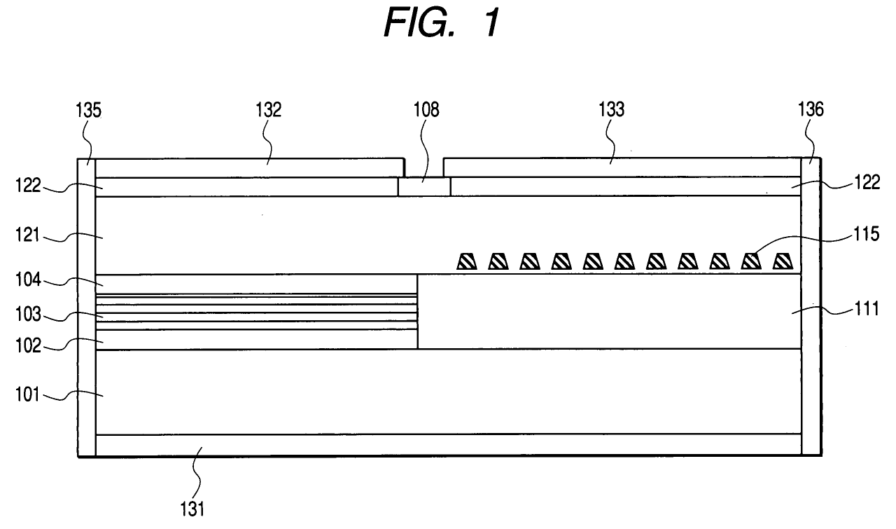

FIGS. 2A and 2B are diagrams for explaining characteristics of the existent device;

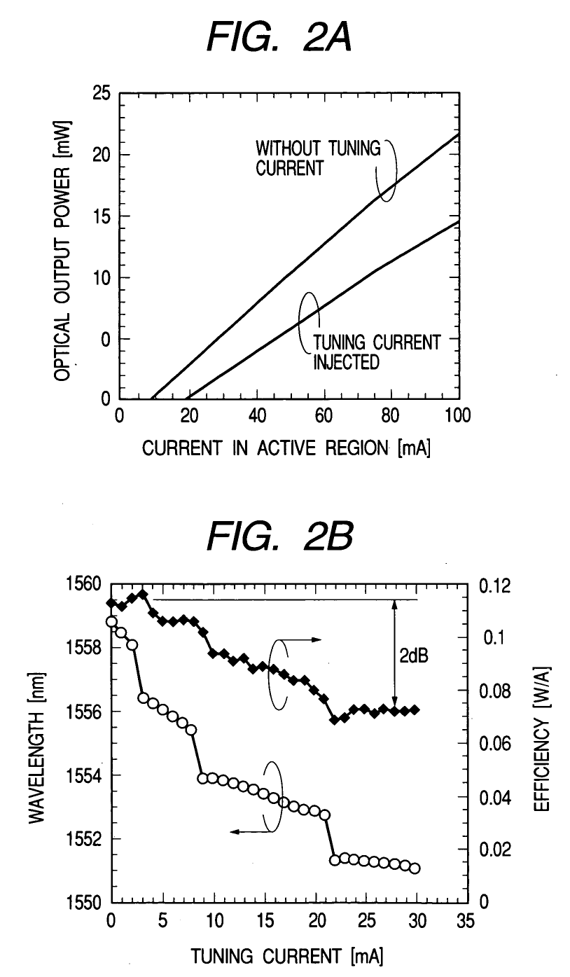

FIGS. 3A and 3B illustrate the device according to a first embodiment of the invention, in which FIG. 3A is a cross-sectional view of a waveguide axis as viewed from its lateral side, FIG. 3B is a cross-sectional view of an active section as viewed from the direction vertical to the axis of the waveguide;

FIGS. 4A to 4D are cross-sectional views showing manufacturing steps of the device according to the first embodiment of the invention;

FIG. 5 is a cross-sectional view of a device according to a modified embodiment of the first embodiment;

FIG. 6 is a cross-sectional view of a device according to another modified embodiment of the first embodiment;

FIG. 7 is a cross-sectional view of a device according to another modified embodiment of the first embodiment;

FIG. 8 is a cross-sectional view of the device according to a second embodiment of the invention, taken along a plane parallel with an optical axis of the device;

FIG. 9 is a cross sectional view showing manufacturing steps of the device according to the second embodiment of the invention;

FIGS. 10A and 10B are a top view and a cross-sectional view taken along a plane parallel to an optical axis of a device, respectively, showing the device according to another embodiment of the invention;

FIGS. 11A and 11B are a top view and a cross-sectional view taken along a plane parallel to an optical axis of the device, respectively, showing the device according to another embodiment of the invention;

FIG. 12 is a graph showing wavelength tuning characteristics in a wavelength tunable laser according to the first embodiment; and

FIG. 13 is a graph showing the change of a driving current for a device during wavelength tuning.

### DESCRIPTION OF THE PREFERRED EMBODIMENTS

Prior to the description of the embodiments of the present invention, the function and effect of the invention will be described in detail.

In the invention, as a result of compensating free carrier loss α_{fc} along with current injection to the DBR section, the following two effects are obtained as the characteristics of the wavelength tunable light source:

(1) Minimization of reduction in optical power upon wavelength tuning; and

(2) Extension of the wave tunable range.

The former is a direct effect of reducing the free carrier loss α_{fc} as described above. The latter is an additional effect obtained by reducing α_{fc}, which contributes greatly to the improvement of the wavelength tunable laser characteristics.

At first, reduction of α_{fc} and the direct effect thereof are to be explained. It is generally considered that the free carrier absorption loss α_{fc} generated along with current injection to the DBR section is in proportion with the injected carrier density N. Accordingly, a relation: α_{fc}=A×n (cm⁻¹) is established, symbol A being a coefficient. On the other hand, the level of the amplifying function generated by the quantum well is represented by a gain coefficient g. Since the gain coefficient g_{DBR} of the DBR section is substantially in proportion with the density N of carriers injected into the quantum well, a relation: g_{DBR}=β×N (cm⁻¹) is established, symbol β being a coefficient determined by the quantum well structure. The values for the coefficients A, β, and a relation between N and n can be adjusted by properly designing the structure of the quantum well formed in the DBR section. Accordingly, by properly designing the structure of the DBR section, g_{DBR}−α_{fc}≈0 can be approached so that the absorption α_{fc} of free carriers generated in DBR can be compensated by g_{DBR}.

Then, the effect that the wavelength tunable range increases if α_{fc} is decreased is to be explained. For the DBR laser to oscillate at a certain mode, the mode gain Gₜₕₘ thereof in the active section has to be equal to the total loss in the laser (αₜₒₜ).

That is, it is necessary that the following relation is established:

αₜₒₜ=Gₜₕₘ (1)

is established.

Further, αₜₒₜ is represented by the following equation:

αₜₒₜ=αᵢ+α_{DBR}+α_{fc} (2)

where αᵢ is an internal loss of a waveguide and α_{DBR} is a reflection loss at a DBR refection mirror. Then, this is given as the following equation:

α_{DBR}=(1/L_{act})×Ln(1/R_{DBR}) (3)

where Ln represents a natural logarithm. L_{act} is an active section length and R_{DBR} is a reflectance determined depending on the structure of the diffraction grating in the DBR section. In equation (2), when α_{fc} can be decreased, αₜₒₜ may not change even when α_{DBR} is increased by so much and laser oscillation is possible. Considering this in view of equation (3), this leads to that laser oscillation can be attained also in a small active section length (L_{act}) in a DBR laser of a small free carrier less (α_{fc}).

On the other hand, an oscillation wavelength mode interval Δλ of the DBR laser that oscillates at a wavelength λ is given by the following equation:

Δλ=λ²/(2×N×L_{act}) (4)

Accordingly, this shows that if the decrease of α_{fc} enables a laser of a smaller active section length to oscillate, Δλ in equation (4) also increases. The continuous wavelength tunable range of the DBR laser is in proportion with the oscillation wavelength mode interval of the DBR laser. Accordingly, it will be understood in view of the relation of formula (4) that the continuous wavelength tunable range is also large in a laser with small L_{act}.

<Embodiment 1>

A first embodiment of the present invention is a wavelength tunable laser device with a wavelength band of 1.55 μm.

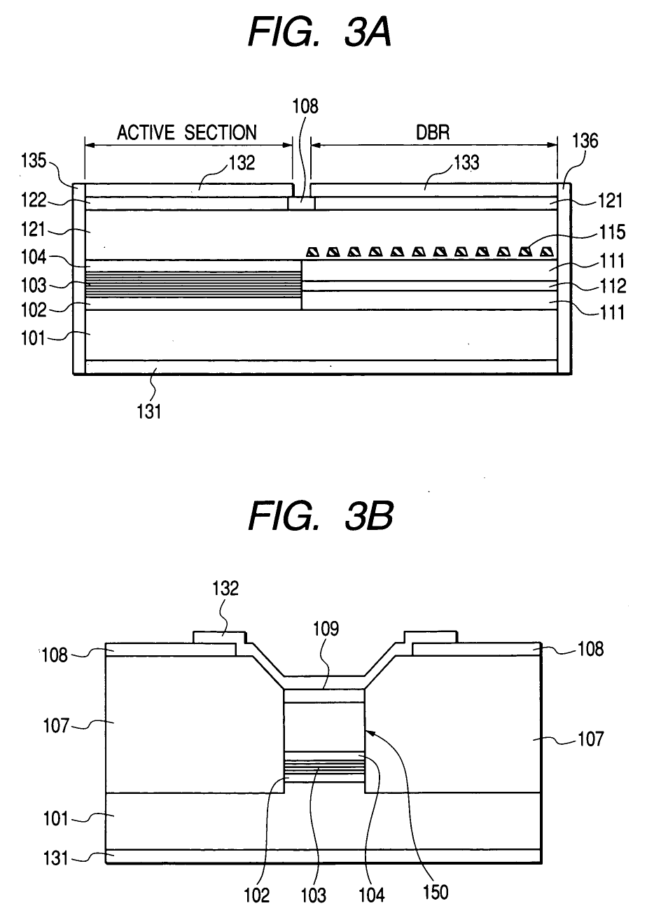

FIGS. 3A and 3B illustrate the device according to a first embodiment of the invention, in which FIG. 3A is a cross-sectional view of a waveguide axis as viewed from its lateral side, FIG. 3B is a cross sectional view of an active section as viewed from the direction vertical to the axis of the waveguide. Details for each of the figures are to be explained in accordance with the following descriptions of the manufacturing steps thereof.

A wavelength tunable laser device in this embodiment is composed of an active section and a DBR section that are respectively provided with an active section electrode 132 and an amplifier electrode 133 independently of each other. The active section and the DBR section are electrically separated from each other.

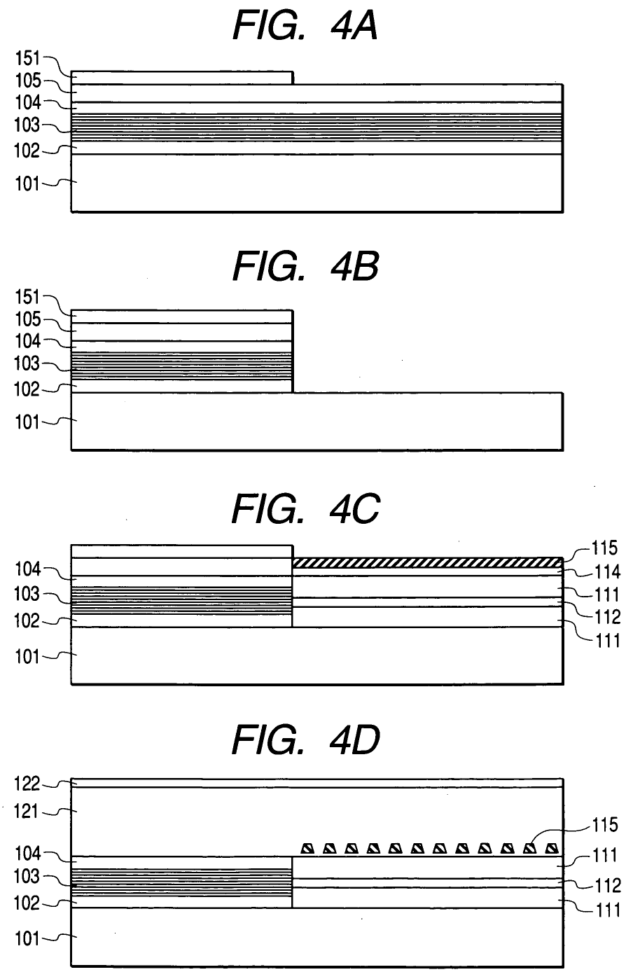

A description is to be made simply in accordance with manufacturing steps. FIGS. 4A to 4D are cross-sectional views of a device illustrating the manufacturing steps. At first, as can be seen with reference to FIG. 4A, a layer structure of an active section is formed on an n-InP substrate 101 in a first crystal growing step. The layer structure of the active section comprises an n-side confinement layer 102, MQW (Multiple Quantum Wells) 103, a p-side confinement layer 104 and a p-clad layer 105. The multiple quantum well active layer 103 is formed of seven pairs of well layers and barrier layers stacked periodically, each well layer being 6 nm in thickness and each barrier layer being 10 nm in thickness. Thus, the active layer 103 is designed so as to attain sufficient characteristics as a laser. The band gap wavelength in the active section was set to 1550 nm.

After forming the layer structure of the active section, a layer structure of the DBR section is formed in a second crystal growing step. The layer structure of the DBR section formed in the second crystal growing step is formed by using a butt-joint growth as shown in the step of FIG. 4.

The butt-joint growth is a growing method of growing and forming a plurality of waveguides in abutment. The process usually comprises three steps: a crystal growing of a first waveguide structure, an etching step and a crystal growing of a second waveguide. Specifically, this is described in the first embodiment of the invention referring to FIG. 4. In the first crystal growing step, a stacked structure of an active section is formed on a semiconductor substrate. In the second stage, only the active section is left in the stacked structure described above and other sections are selectively removed by etching. Subsequently, in the second crystal growing step, a desired stacked structure is grown as a DBR section. Thus, stacked structures of the active section and the DBR section are formed in abutment on the same semiconductor substrate.

Silicon nitride (hereinafter simply referred to as SiN) is covered above the layer structure of the active section to form a protection mask 151 at a laser portion (FIG. 4A). Using the SiN mask 151, the layer structure in the active section is removed by etching as shown in FIG. 4B. This etching is carried out as far as the n-InGaAsP optical waveguide layer 102 and stopped selectively on the n-InP substrate. For the etching, any of dry etching such as RIE (Reactive Ion Etching), selective wet etching using a solution comprising phosphoric acid or sulfuric acid as a main ingredient and both of them may be used for instance.

Successively, as shown in FIG. 4C a layer structure of a DBR section is formed on the exposed n-InP substrate 101. A p-InP spacer layer 114 and a layer 115 for diffraction grating, e.g., an InGaAsP layer with a band gap wavelength of 1.15 μm are formed on an InGaAsP optical waveguide layer 111, a quantum well layer 112 and an optical waveguide layer 111 stacked alternately. The optical waveguide layer is designed to have a band gap wavelength of about 1.40 μm to 1.43 μm. Further, the quantum well layer 131 is designed to have a band gap wavelength of about 1550 nm. In order to obtain a desired reflectance in the DBR section, the layer for the diffraction grating is designed to have a band gap wavelength of 1.15 μm. A usual method may suffice for the butt-joint growth, and its detailed description will be omitted.

After forming the layer structure of the DBR section, the layer 115 for the diffraction grating is fabricated into a grating structure by applying the usual drawing technique and etching technique. The period of the diffraction grating is controlled so that a Bragg's wavelength is 1550 nm at room temperature (25° C.). In this embodiment, while a method of formation by holographic-exposure drawing and wet etching is adopted, other methods such as electron beam drawing or dry etching may also be used. After forming the diffraction grating for the DBR section, a p-InP clad layer 121 and a p-InGaAs ohmic contact layer 122 are formed (FIG. 4D).

Succeeding to the third crystal growing step, a BH structure (Buried Heterostructure) as shown in FIG. 3B is formed. RIE (Reactive Ion Etching) using a methane series gas is used for the formation of a mesa stripe 150 extending in the direction of an optical axis of an optical resonator. To remove damage to the crystal surface caused by dry etching, after slightly treating the etched surface with a solution comprising hydrobromic acid (HBr) and bromine as the main ingredient, the active layer and the optical waveguide layer are buried with iron (Fe)-doped high resistance InP 107. By way of the steps described above, the BH structure is completed.

Successively, the crystal surface is passivated by SiO₂ 108 at the wafer surface. In the upper portion 109 above the mesa stripe 150, the SiO₂ film is removed for current supply and a p-electrode 132 for the active section and a p-electrode 133 for the DBR are formed. Succeeding to the formation of the p-electrodes, the rear of the wafer is polished to provide the wafer with a thickness of about 100 μm and an n-electrode 131 is formed on the rear face. After forming the n-electrode, the wafer is cleaved to individual semiconductor laser devices each having a desired length. The semiconductor laser device is formed with a high reflective film 135 and an anti-reflective film 136 at the rear face and front face thereof, respectively.

The structure of this embodiment has an effect of minimizing degradation of current-optical power characteristics upon wavelength tuning of the wavelength tunable DBR laser. In particular, it provides an effect for reduction in the degradation of the optical power efficiency (slope efficiency) per unit current.

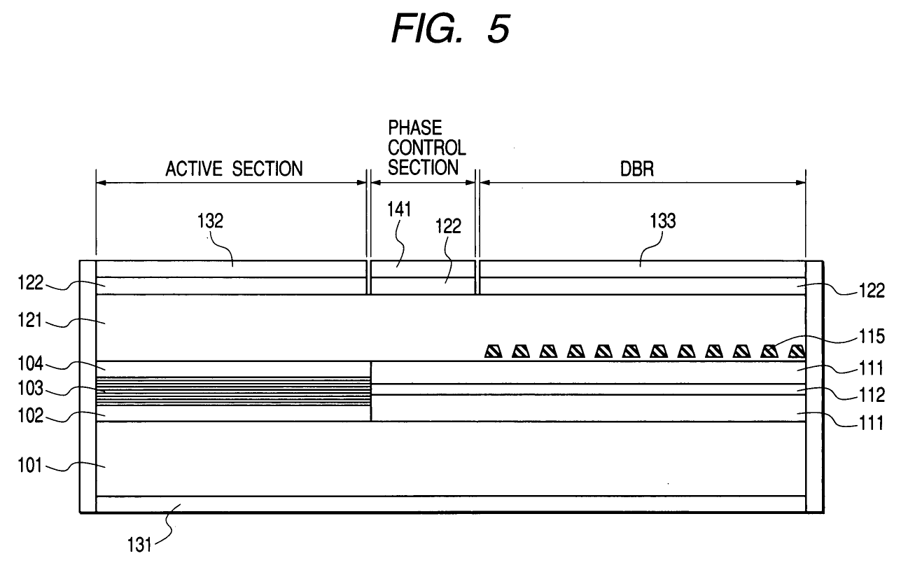

FIG. 5 shows a modified one of the first embodiment. This modified embodiment elates to the provision of a phase controlling section between a DBR section and an active section. FIG. 5 is a cross-sectional view taken along a plane parallel with an optical axis of an optical resonator. Since the role of the phase control section in a wavelength tunable DBR laser has no substantial difference from that of usual cases, its detailed description will be omitted. In the embodiment shown in FIG. 5, a quantum well layer 112 is introduced also in the phase control section. Accordingly, compensation for the free carrier loss as an object of the invention is possible also in the phase control section. Manufacturing steps are the same as those of the embodiment shown in FIGS. 3 and 4. In FIG. 5, reference numeral 141 denotes a p-electrode of the phase control section.

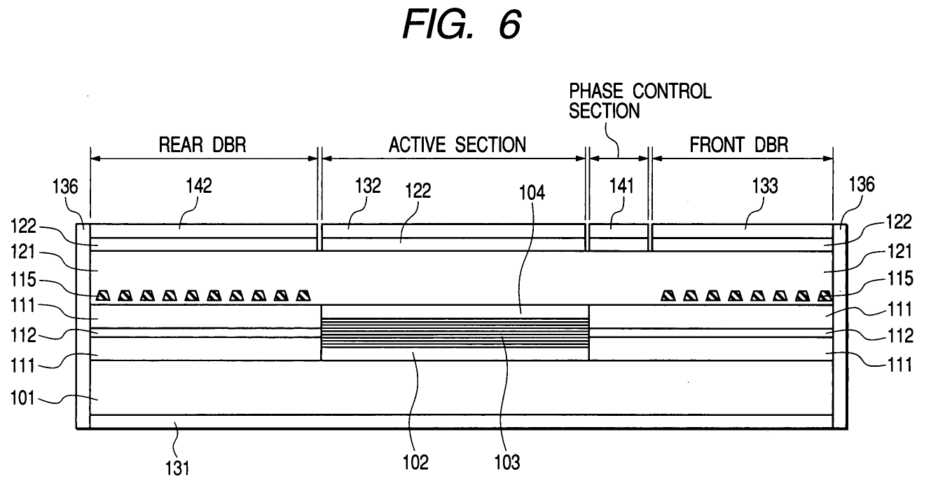

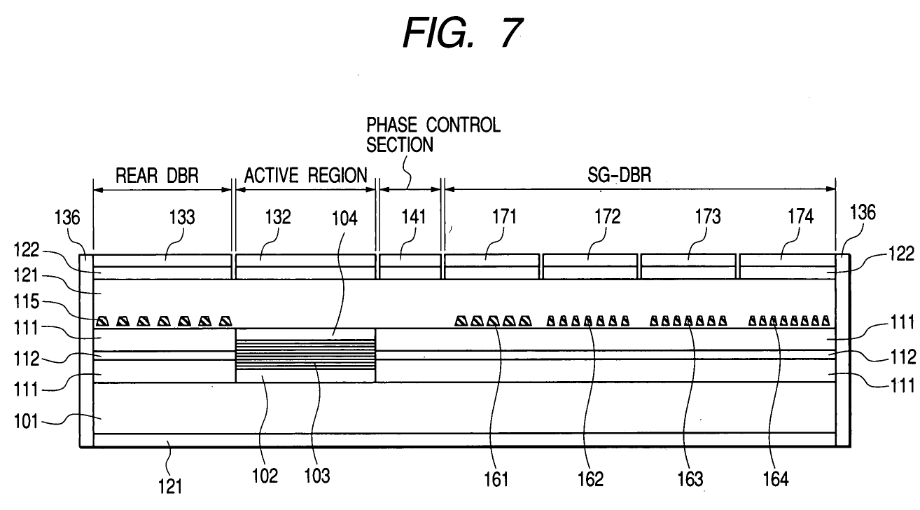

Further, FIG. 6 shows an example of providing the DBR sections in the front and rear of the active section. FIG. 6 is a cross-sectional view taken along a plane parallel with an optical axis of an optical resonator. Reference numeral 142 represents a p-electrode of a rear DBR section. Further, as exemplified in FIG. 7, it is apparent that the invention is applicable to an SG (Sampled Grating) structure comprising a plurality of diffraction gratings with periods slightly different from each other arranged in the DBR section. In the case of the SG structure, gratings 161, 162, 163, and 164 with respective different periods are arranged so that they are controlled by wavelength control electrodes 171, 172, 173, and 174, respectively. Accordingly, the length of the DBR section increases compared with the usual DBR. In such a case, attenuation of light propagating in the DBR section results in a significant problem. The structure of compensating the light attenuation in the DBR section as in this embodiment is particularly effective for the SG-DBR. In this invention, four types of SGs are provided in front of the phase control section, the invention is not restricted with respect to the number of SGs. Further, in a case where SG-DBR are provided in the front and rear of the active section, the effect of the invention can be increased further.

Also for the material constituting the semiconductor laser device or the waveguide structure of the device, the invention is not restricted to the material or the structure of the embodiment. Referring to the material constituting the active section and the DBR section, while InGaAsP type materials are described in this embodiment, InAlAs series materials or InGaAlAs series materials can also be used for a portion or the entire portion of the active section or the DBR section. Also for the waveguide structure, the invention is applicable also to a ridge waveguide structure in addition to the buried heterostructure.

In this embodiment, the description has been made of the laser comprising InGaAsP series and InGaAlAs series materials but the configuration of the invention is not restricted to the materials described above but the invention is applicable generally to lasers having a DBR structure formed of group III-V compound semiconductors, etc.

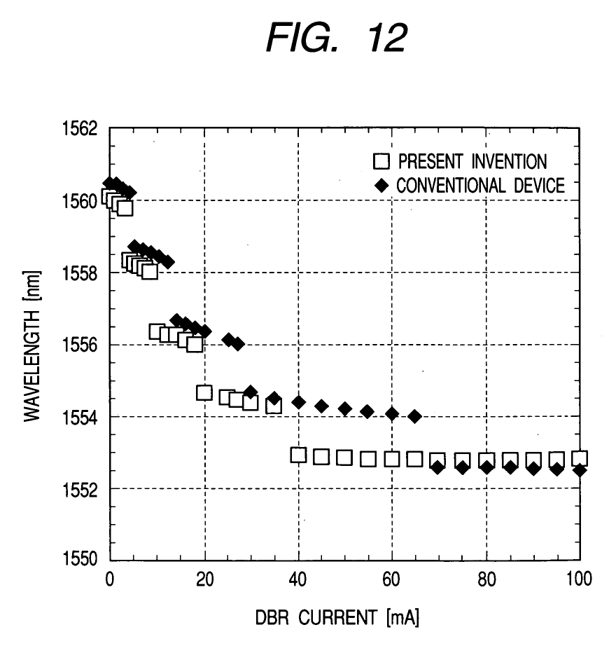

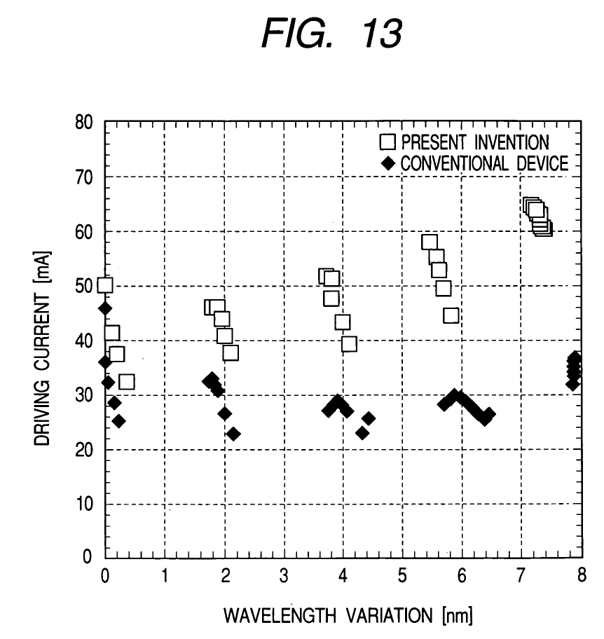

The effect of this embodiment is to be described with reference to FIGS. 12 and 13. FIG. 12 is a graph showing the result of an experiment for the wavelength tunable characteristics of a wavelength tunable laser to which the invention is applied. The electric current injected into a DBR section is expressed on the abscissa and the amount of change in the oscillation wavelength is expressed on the ordinate. In FIG. 12, the experimental result of a laser to which the invention is applied and that of a laser to which the invention is not applied are shown together for comparison. As shown in the graph, as the current injected into the DBR section increases, the wavelength is shortened. The amounts of wavelength change (variable wavelength) at about 100 mA of an injection current into the DBR section are substantially the same between the device to which the invention is applied and an existent device not inserting the quantum well to the DBR section.

FIG. 13 shows a driving current of a device actually measured upon wavelength tuning. In the same manner as in FIG. 12, a laser of the invention and a laser to which the invention is not applied are shown together for comparison. The amount of the wavelength change is expressed on the abscissa and the driving current injected to the active section for obtaining an optical power at +3 dBm is expressed on the ordinate. In the existent device, the driving current increases along with increase in the amount of the wavelength change. The device driving current increases 1.5 times or more that in the initial state when the wavelength change is 7 nm. On the contrary, in the device of the invention, change in the driving current is reduced to about 10% or less also when changing the wavelength by 7 nm or more. This shows that the gain is generated by the quantum well inserted in the DBR section to thereby compensate a loss upon wavelength tuning.

As described above, it has been confirmed that the invention has an effect of decreasing the driving current for obtaining an optical power with +3 dBm while changing the wavelength by about 7 nm in a wavelength tunable laser, to about one-half compared with the existent laser.

<Embodiment 2>

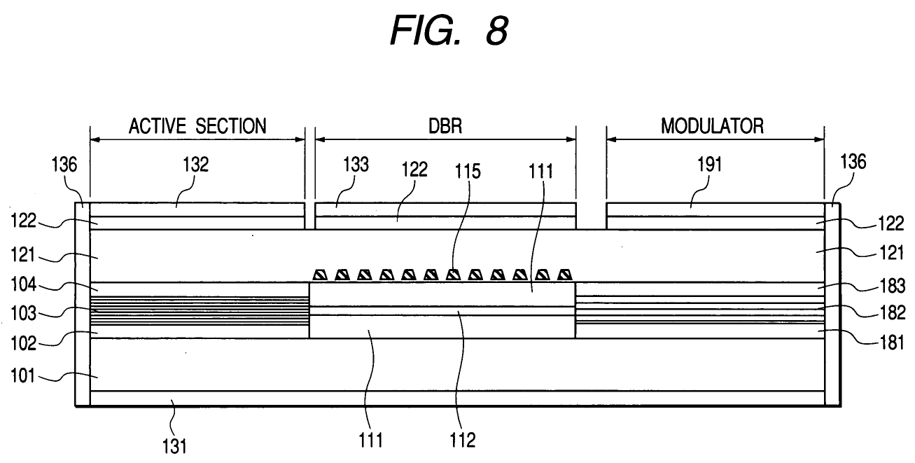

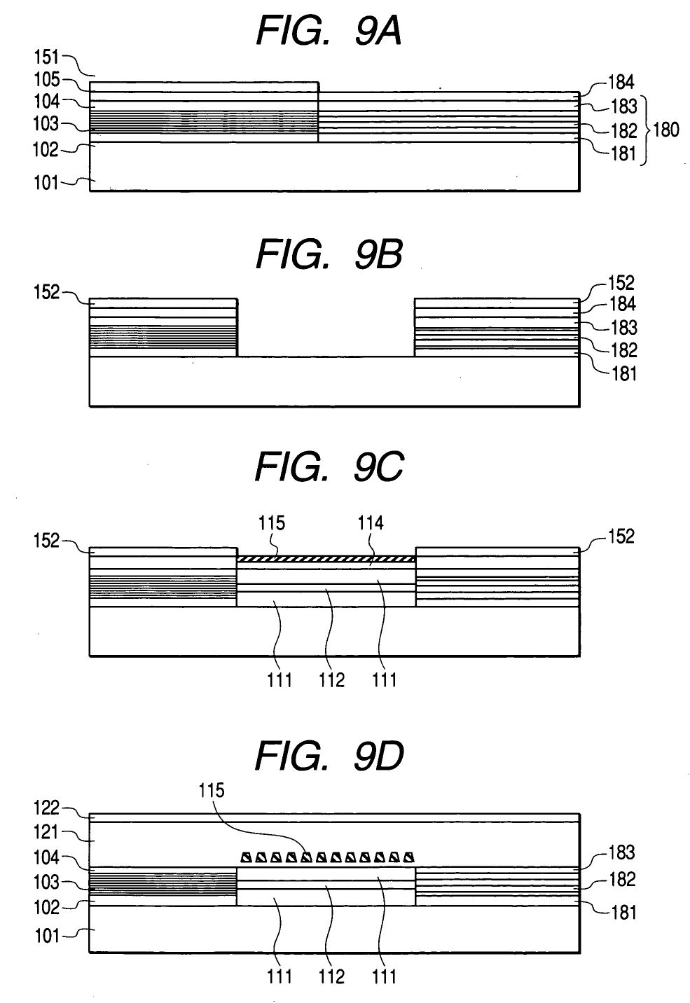

A second embodiment of the invention concerns a structure in which an EA (Electro Absorption) modulator is integrated with a DBR wavelength tunable laser diode. FIG. 8 is a cross-sectional view taken along a plane parallel with an optical axis of a resonator. The wavelength tunable laser diode in this embodiment is composed of an active section and a DBR section that are respectively provided with an active section electrode 132 and an amplifier electrode 133 independently of each other. An electrode 191 for the modulator is formed in the EA modulator. The stacked structure and manufacturing steps of the active section and the DBR section are basically the same as those of the first embodiment. FIG. 9 is a cross-sectional view of the device, showing the manufacturing steps thereof. In FIG. 9, identical portions carry identical reference numerals.

At first, as can be seen in view of FIG. 9A, a layer structure of an active section is formed on an n-InP substrate 101 by a first crystal growing step. The layer structure of the active section comprises an n-side confinement layer 102, a multiple quantum well active layer 103, a p-side optical confinement layer 104 and a p-clad layer 105. The multiple quantum well active layer 103 is formed of seven pairs of well layers and barrier layers stacked periodically, each well layer being 6 nm in thickness and each barrier layer being 10 nm in thickness. Thus, the active layer 103 is designed so as to attain sufficient characteristics as a laser.

After forming the layer structure of the active section, a layer structure of the EA modulator is formed in a second crystal growing step. A butt-joint growth is used for the layer structure stack of the EA modulator. SiN is covered on the layer structure of the active section to form a protection mask 151 for the laser portion. The layer structure of the active section is removed by etching using the SiN mask 151 as shown in FIG. 4B. Etching is performed as far as an n-InGaAsP optical waveguide layer and etching is stopped selectively on the n-InP substrate. For the etching, dry etching such as RIE (Reactive Ion Etching), selective wet etching using a solution comprising phosphoric acid or sulfuric acid as a main ingredient, or both of them may be used.

Successively, as shown in FIG. 9A, a layer structure of the EA modulator is formed on the exposed n-InP substrate. An optical absorption layer 180 is formed, on the n-InP substrate 101, at a portion corresponding to the EA modulator portion. The optical absorption layer 180 comprises three layers of an n-InGaAsP optical confinement layer 181, MQW (Multiple Quantum Wells) 182 and an undoped InGaAsP optical confinement layer 183. The MQW layers 182 comprise ten periods of well layers (each 7 mm thickness) made of an InGaAsP type material and barrier layers (5 nm thickness) stacked one on another. The values of MQW structure for the EA modulator are not restricted to those of this embodiment. Although the thickness, composition and the number of periodicals of the quantum layer and the barrier layer may be adjusted optionally to obtain desired modulation characteristics, this does not change the effects of the invention.

After forming the layer structure of the EA modulator, a layer structure of the DBR section is formed in a third crystal growing step as shown in FIG. 9B. The layer structure of the DBR modulator is formed by using butt-joint growth as shown in FIGS. 9A to 9D. SiN is covered on the layer structure of the active section and the EA modulator to form a protection mask 152 for a laser portion. The layer structure of the active section is removed by etching using the SiN mask 151 as shown in FIG. 9B. Etching is conducted as far as the n-InGaAsP optical waveguide layer and etching is stopped selectively on the n-InP substrate. For the etching, dry etching such as RIE (Reactive Ion Etching), selective wet etching using a solution comprising phosphoric acid or sulfuric acid as a main ingredient, or both of them may be used.

Successively, as shown in FIG. 9C, a layer structure of a DBR section is formed on the exposed n-InP substrate 101. A p-InP spacer layer 114 and a diffraction grating layer 115 are formed on an InGaAsP optical waveguide layer 111, a quantum well layer 112, and an optical waveguide layer 111 stacked alternately. The optical waveguide layer is designed to have a band gap wavelength of about 1.43 μm. Further, the quantum well layer 131 is designed to have a band gap wavelength of about 1550 nm. Further, the diffraction grating layer is designed to have a band gap wavelength of 1.15 μm in order to obtain a desired reflectance in the DBR section.

After forming the layer structure of the DBR section, the layer 115 for the diffraction grating is fabricated into a grating structure by applying usual drawing technique and etching technique. The period of the diffraction grating is controlled so that the oscillation wavelength of a DFB laser is 1550 nm at room temperature (25° C.). In the embodiment, while a method of formation by holographic exposure drawing and wet etching is adopted, other methods such as electron beam drawing or dry etching may also be used. After forming the diffraction grating for the DBR section, a p-InP clad layer 121 and a p-InGaAs ohmic contact layer 122 are formed.

Succeeding to the third crystal growing step, a BH structure (Buried Heterostructure) as exemplified in FIG. 3B is formed in the same manner as in the first embodiment. Reactive ion etching using a methane series gas is used for the formation of a mesa stripe. To remove damage to the crystal surface caused by dry etching, after slightly treating the etched surface with an HBr type solution, the active layer and the optical waveguide layer were buried with iron (Fe)-doped high resistance InP 107. By way of the steps described above, the BH structure (Buried Heterostructure) is completed. Successively, the wafer surface is passivated by SiO₂ 108. In the upper portion 109 above the mesa stripe 150, the insulating film is removed for current supply and p-electrodes 132, 133 are formed. Succeeding to the formation of the p-electrodes, the wafer is polished to a thickness of as small as about 100 μm and an n-electrode 131 was formed. After forming the electrode, the device is cleaved to a desired length. A high reflective film 135 and the anti-reflective film 136 are formed at the rear face and the front face, respectively, in the laser device.

While this embodiment shows a configuration of integrating the EA modulator, an SOA (Semiconductor Optical Amplifier) may also be integrated instead of the EA modulator. The optical amplifier can be integrated by merely changing the MQW structure in the EA modulator portion to a desired structure as an SOA. As a matter of fact, both the optical amplifier and the EA modulator can be integrated.

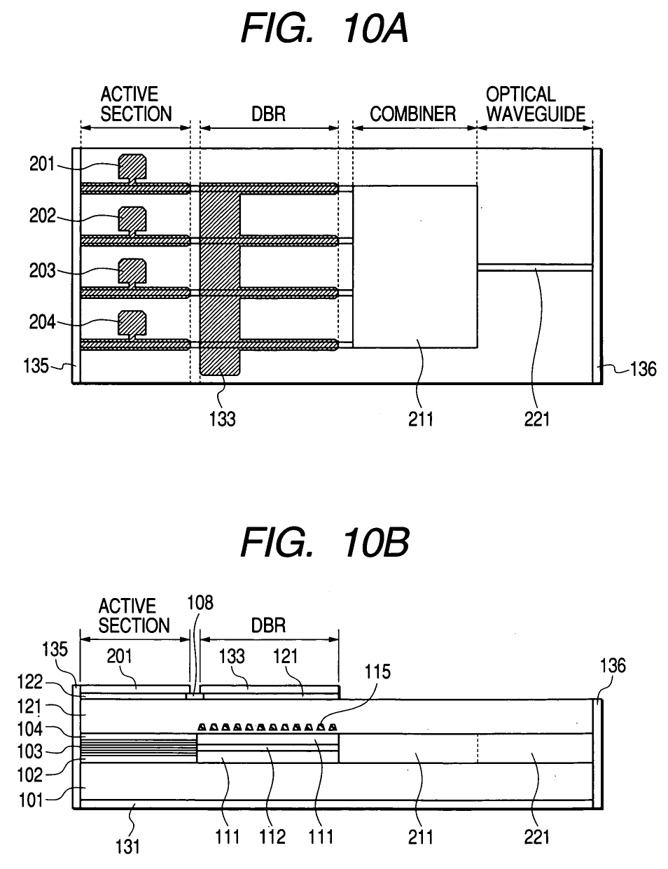

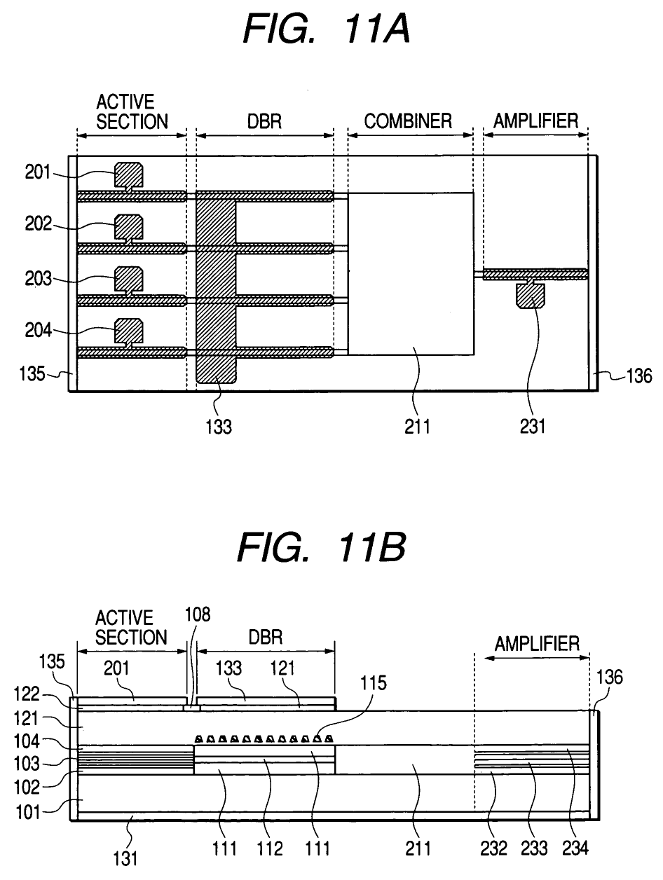

The first and the second embodiments described above show an example where the active section comprises a single stripe, but a plurality channels of DBR lasers may also be arranged in parallel as shown in FIGS. 10 and 11. FIGS. 10A and 11A are plan views of a device and FIGS. 10B and 11B are cross-sectional views each taken along a plane parallel with the optical axis of an optical resonator.

FIGS. 10A and 10B show an example in which DBR lasers with four channels are integrated in parallel. Reference numerals 201, 202, 203 and 204 each represents an electrode for each of the channels, and reference numeral 133 represents an electrode for the DBR section. Further, in this embodiment, four channels are optically combined to an optical combiner 221 and, further, led to the outside by way of a light waveguide 221. Other portions identical with those shown previously carry like reference numerals.

The embodiment shown in FIGS. 11A and 11B is an example of providing an optical amplifier 231 for the optical waveguide 221 in the example of FIG. 10. Large optical signals can be obtained by optical amplification. Other portions identical with those described previously carry the same reference numerals, for which detailed explanation will be omitted.

<Comparison with Prior Art>

The concept of providing the DBR section with the optical amplification function was reported in the Electronics Engineering Article, IEEE Photonics Technology Letters, Vol. 3, No. 10, pp 866 to 868, issued in 1990. In this example, an active layer constituted as a bulk is disposed in the DBR section so as to provide the DBR section with an amplifying function. On the contrary, in the invention, the quantum well layer is inserted in the DBR section. In the invention using the quantum well active layer, the current necessary for generating the amplifying function is smaller compared with a case of using the bulk active layer. Accordingly, the structure of inserting the quantum well layer as in the invention can enjoy the compensation effect for the loss in the DBR section effectively by smaller electric current.

On the other hand, the structure in which the quantum well layer is present in the DBR section has been also proposed in JP-A No. 5-55689 and JP-A No. 8-139413. A difference between the existent structure described above and the invention is to be described below.

JP-A No. 5-55689 discloses a constitution of introducing a strained quantum well structure to an optical waveguide of a DBR section. It is described that the purpose of introducing the strained quantum well to the DBR section is to promote the plasma effect in the section so as to improve the wavelength tuning efficiency. For this purpose, the band gap wavelength of the DBR section is set to 1.3 μm relative to the oscillation wavelength band of 1.55 μm. On the contrary, the object of the invention is to minimize the attenuation of light along with the wavelength tuning in the DBR section. The band gap wavelength of the quantum well in the DBR section is set to a 1.55 μm band substantially equal to the oscillation wavelength. This can provide an amplifying function for light with the oscillation frequency in the DBR section. Use of this amplifying function compensates attenuation of light in the DBR section along with the wavelength tuning.

Further, JP-A No. 8-139413 discloses a structure of introducing a quantum well structure in common with an active section and a DBR section as a method of controlling the band gap wavelength of a wavelength tunable DBR laser. Comparatively with this prior art, the invention comprises a structure in which the DBR section has a quantum well layer independent of the active section. The invention provides an effect not found in JP-A No. 8-139413.

The present invention can provide a DBR wavelength tunable laser diode having large optical power and capable of high-speed wavelength switching.

Reference numerals described above will briefly be explained below.

101 . . . n-InP substrate, 102 . . . n-InGaAs optical confinement layer, 103 . . . multiple quantum well active layer, 104 . . . p-InGaAs optical confinement layer, 105 . . . p-InP clad layer, 107 . . . Fe added InP, 108 . . . silicon oxide film, 109 . . . insulation film removed portion, 111 . . . InGaAsP optical confinement layer, 112 . . . quantum well layer, 114 . . . p-InP spacer layer, 115 . . . InGaAsP diffraction grating layer, 121 . . . p-InP clad layer, 122 . . . p-InGaAs contact layer, 131 . . . n-electrode, 132 . . . p-electrode for active section, 133 . . . p-electrode for DBR section, 135 . . . high reflective film, 136 . . . anti-reflective film, 141 . . . p-electrode for phase control section, 142 . . . p-electrode for rear DBR section, 161 . . . diffraction grating, 162 . . . diffraction grating, 163 . . . diffraction grating, 163 . . . diffraction grating, 171 . . . SG-DBR electrode, 172 . . . SG-DBR electrode, 173 . . . SG-DBR electrode, 174 . . . SG-DBR electrode, 181 . . . n-InGaAsP optical confinement layer, 182 . . . multiple quantum well optical absorption layer, 183 . . . INGaAsP optical confinement layer, 184 . . . p-InP clad layer, 191 . . . p-electrode for EA modulator, 201 . . . electrode for first channel active section, 202 . . . electrode for second channel active section, 203 . . . electrode for third channel active section, 204 . . . electrode for fourth channel active section, 211 . . . optical combiner, 221 . . . optical waveguide, 231 . . . electrode for optical amplifier, 232 . . . n-optical confinement layer for optical amplifier, 233 . . . optical amplifier quantum well layer, 234 . . . p-side optical confinement layer for optical amplifier.

What is claimed is:

1. A wavelength tunable DBR laser diode comprising:
an optical waveguide section including an active section; and
a distributed Bragg reflector connected optically to the optical waveguide section;
wherein an optical waveguide section of the distributed Bragg reflector has a quantum well layer which has the number of one or more layers of periods and a structure independent of the optical waveguide section including the active section and which is disposed at least at a section extending in a direction of an optical axis of the distributed Bragg reflector, and the quantum well layer of the Bragg reflector has a function of amplifying an oscillation wave length of the wavelength tunable DBR laser diode.

2. A wavelength tunable DBR laser diode according to claim 1, wherein the optical waveguide section including the active section is optically connected to the distributed Bragg reflector by Butt-joint.

3. A wavelength tunable DBR laser diode according to claim 1, wherein a semiconductor optical amplifier is further optically connected to one end of an optical waveguide structure having the distributed Bragg reflector and the optical waveguide including the active section.

4. A wavelength tunable DBR laser diode according to claim 1, wherein a semiconductor optical modulator is further optically connected to one end of an optical waveguide structure having the distributed Bragg reflector, and the optical waveguide including the active section.

5. A wavelength tunable DBR laser diode according to claim 1, wherein a phase control section is optically connected between the distributed Bragg reflector and the optical waveguide section including the active section, and the quantum well layer which has the number of one or more layers of periods and a structure independent of the optical waveguide section including the active section and which is disposed at least at a portion or an entire portion of the distributed Bragg reflector and the phase control section.

6. A wavelength tunable DBR laser diode according to claim 1, wherein the distributed Bragg reflector has a diffraction grating, which includes diffraction grating areas differing in period located in at least a portion of the diffraction grating.

7. A wavelength tunable DBR laser diode,
wherein optical waveguide sections each having a distributed Bragg reflector and an optical waveguide section including an active section optically connected to each other are disposed in parallel, and one end of the distributed Bragg reflector is optically connected to one end of an optical combiner; and
wherein an optical waveguide section of the distributed Bragg reflector has a quantum well layer which has the number of one or more layers of periods and a structure independent of the optical waveguide section including the active section and which is disposed at least at a section extending in a direction of an optical axis of the distributed Bragg reflector,

8. A wavelength tunable DBR laser diode according to claim 8, wherein a semiconductor optical amplifier is further connected optically to the other end of the optical combiner.

9. A wavelength tunable DBR laser diode according to claim 1, wherein
first and second distributed Bragg reflectors are disposed, respectively, on both sides of the optical waveguide section including the active section, and
each of the optical waveguide sections of the first and the second distributed Bragg reflector has a quantum well layer which has the number of one or more layers of periods and a structure independent of the optical waveguide section including the active section and which is disposed at least at a section extending in a direction of an optical axis of the distributed Bragg reflector.

10. A wavelength tunable DBR laser diode according to claim 9, wherein at least one phase control section is optically connected between the first and the second distributed Bragg reflector and the optical waveguide section including the active section; and
wherein the quantum well layer has the number of one or more layers of periods and a structure independent of the optical waveguide section including the active section and is disposed at least at a portion or an entire portion of the distributed Bragg reflector and the phase control section.
